(19) United States
(12) Patent Application Publication
(10) Pub. No.: US 2012/0268911 A1
(43) Pub. Date: Oct. 25, 2012

(54) PROTECTIVE SLEEVE FOR TOUCH CONTROL ELECTRONIC DEVICE

(75) Inventor: Yu-Kai LIN, New Taipei City (TW)

(73) Assignee: KO JA (CAYMAN) CO., LTD.

(21) Appl. No.: 13/093,044

(22) Filed: Apr. 25, 2011

(51) Int. Cl. H05K 7/00

(52) U.S. Cl. 361/807

(57) ABSTRACT

In a protective sleeve for a touch control electronic device, the touch control electronic device has a touch screen and a signal receiving unit. The protective sleeve includes a body and a cover. The body has a first sensor and an accommodating portion for receiving the touch control electronic device. The cover is connected to one side of the body and turned over to cover the body. The cover has a film keyboard coupled to the signal receiving unit and a second sensor located to correspond to the first sensor. The first sensor and the second sensor sense with each other to turn off the film keypad when the cover covers the body. Thus, the protective sleeve of the present invention has an input function without occupying a display area of the touch control electronic device. Further, the present invention conforms to the requirements for compact design.

### BACKGROUND OF THE INVENTION

1. Field of the Invention

The present invention relates to a protective sleeve, and in particular to a protective sleeve for a touch control electronic device.

2. Description of Prior Art

With the advancement of science and technology, various kinds of electronic devices are proposed and widely used in our daily life. Currently, many kinds of touch control electronic devices are available in the market, such as a smart phone or a portable tablet computer which allows a user to read electronic books. Such a touch control electronic device has a primary advantage that the user can directly input commands through a menu shown in a touch screen or input characters or commands into the electronic device through a virtual keyboard. In this way, an external actual keyboard can be omitted to thereby make the touch control electronic device to be more compact.

Usually, such a touch control electronic product is disposed into a protective sleeve for protecting the outer surface of the electronic product against scrapes. However, in practice use, when the user intends to use the virtual keyboard shown on the touch screen of the touch control electronic product, a portion of the display area of the touch screen is inevitably occupied by the virtual keyboard, which reduces the area of a window for editing documents or viewing data. Thus, this problem makes the device inconvenient in use.

If a regular keyboard or keypad is electrically connected into the protective sleeve, such a keyboard or keypad, which will increase the thickness of the whole protective sleeve, does not conform to the requirements for compact design. On the other hand, even though a thin keypad is provided in the protective sleeve, there is still a problem as follows. When the user intends to cover the protective sleeve on the electronic device without turning off the power of the electronic device, keys of the flexible keypad may be activated unintentionally to input commands into the electronic product because the power of the keyboard is not turned off yet.

Therefore, it is an important issue for the present Inventor to solve the above-mentioned problems.

### SUMMARY OF THE INVENTION

The present invention is to provide a protective sleeve for a touch control electronic device, which has an input function and does not need to occupy a display area of the touch screen of the electronic device.

The present invention is to provide a protective sleeve for a touch control electronic device, which is capable of controlling the ON/OFF of the input function and conforming to the requirements for compact design.

The present invention provides a protective sleeve for a touch control electronic device, the touch control electronic device having a touch screen and a signal receiving unit, the protective sleeve including:

a body having an accommodating portion for receiving the touch control electronic device, the accommodating portion being provided with an opening for showing the touch screen, the body being provided with a first sensor; and

a cover connected to one side of the body and turned over to cover the body, the cover being provided with a film keyboard coupled to the signal receiving unit and a second sensor located to correspond to the first sensor, the second sensor being coupled to the film keypad to control the ON/OFF of the film keypad;

wherein the first sensor and the second sensor sense with each other to turn off the film keypad when the cover covers the body.

In comparison with prior art, the present invention has advantageous features as follows. Since the protective cover has a film keypad coupled to the signal receiving unit of the touch control electronic device, the user can input commands into the touch control electronic device through the film keypad of the protective sleeve, which is convenient in use without occupying the display area of the touch screen of the electronic device.

According to the present invention, the first sensor is provided on the body and the second sensor is provided on the cover. Further, when the cover is turned over to cover the body, the first sensor and the second sensor sense with each other to turn off the film keypad. Thus, even though the user turns over the cover to cover the body without turning off the power of the electronic device, the first sensor and the second sensor can still sense with each other to turn off the film keypad, so that the problem that the keys of the film keypad may be unintentionally activated to input commands can be avoided.

### BRIEF DESCRIPTION OF DRAWING

FIG. 1 is a perspective view showing the protective sleeve of the present invention;

FIG. 2 is a perspective view showing that a touch control electronic device is disposed in the protective sleeve of the present invention;

FIG. 3 is a side cross-sectional view showing that a touch control electronic device is disposed in the protective sleeve of the present invention, wherein the cover does not cover the body;

FIG. 4 is a side cross-sectional view showing that a touch control electronic device is disposed in the protective sleeve of the present invention, wherein the cover is turned over to cover the upper surface of the body;

FIG. 5 is a side cross-sectional view showing that a touch control electronic device is disposed in the protective sleeve of the present invention, wherein the cover is turned over in an opposite direction to cover the bottom surface of the body;

FIG. 6 is a perspective view showing the protective sleeve of another embodiment of the present invention; and

FIG. 7 is a perspective view showing the protective sleeve of a further embodiment of the present invention.

### DETAILED DESCRIPTION OF THE INVENTION

The detailed description and technical contents of the present invention will become apparent with the following detailed description accompanied with related drawings. It is noteworthy to point out that the drawings is provided for the illustration purpose only, but not intended for limiting the scope of the present invention.

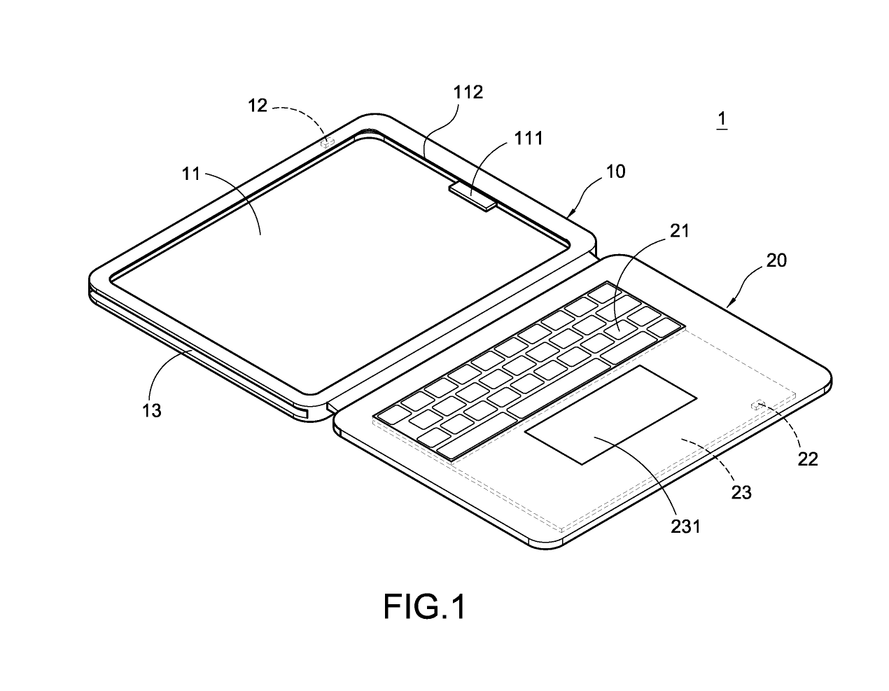

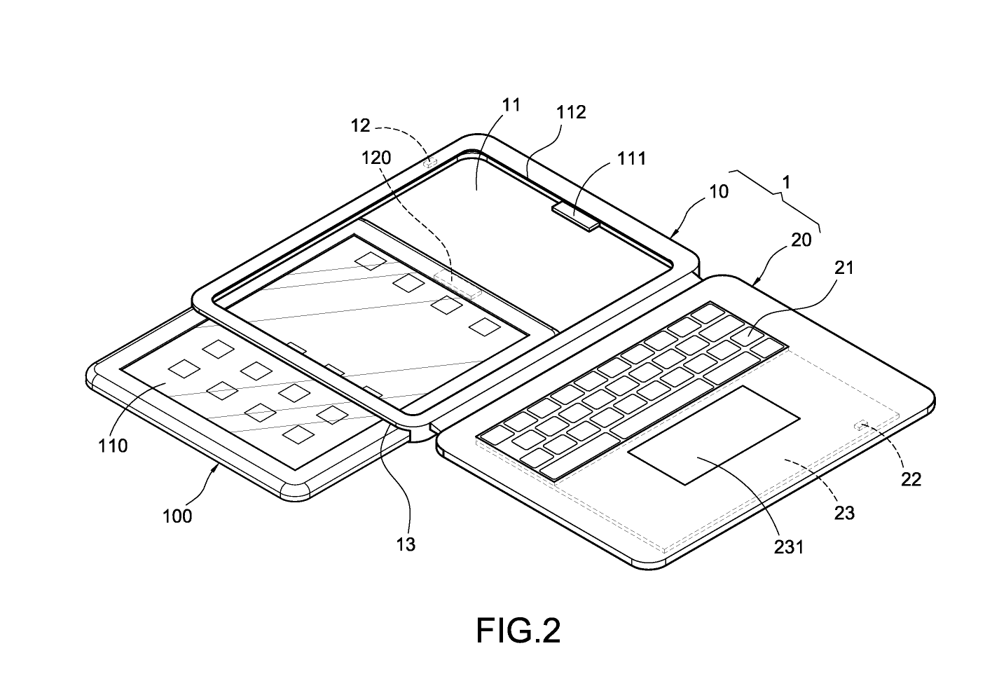

Please refer to FIGS. 1 and 2. The present invention relates to a protective sleeve 1 for a touch control electronic device 100. The protective sleeve 1 includes a body 10 and a cover 20. As shown in FIG. 2, the touch control electronic device 100 is formed into a rectangular shape, and it has a touch screen 110 and a signal receiving unit 120. A command menu, documents or data from the Internet can be displayed on the touch screen 110. The signal receiving unit 120 is wired receiving unit (such as a connecting port) provided in the touch control electronic device 100. When the touch control electronic device 100 is used alone, the signal receiving unit 120 allows an external transmission line (not shown) to be inserted therein, thereby charging the electronic device 100 or accessing data. Since the touch screen 110 and the signal receiving unit 120 of the touch control electronic device 100 are well known and belong to prior art, so that the description thereof is omitted for clarity.

The protective sleeve 1 of the present invention is made of flexible materials (such as rubber). The protective sleeve 1 may be made by integrally forming the body 10 and the cover together, or by connecting the respective body 10 and cover 20 together.

The body 10 is formed into a rectangular shape and has an accommodating portion 11. The accommodating portion 11 is provided with a connector 111 coupled to the signal receiving unit 120 and an opening 112 for showing the touch screen 110. At the periphery of the opening 110, the body 10 is provided with a first sensor 12. As shown in FIG. 1, one side of the body 10 is provided with a through sot 13 in communication with the accommodating portion 11. Via the through slot 13, the touch control electronic device 100 can be inserted into the accommodating portion 11 with the signal receiving unit 120 being connected to the connector 111 of the body 10. Of course, the user may enlarge the opening 112 because of the good flexibility of the body 100, so that the touch control electronic device 100 can be inserted into the accommodating portion 11 through the flexible opening 112 directly without providing the through slot 13. It should be noted that the coupling between the connector 111 and the signal receiving unit 120 can be made by electrical wires.

The cover 20 is also formed into a rectangular shape and connected to one side of the body 10. The cover 20 can be turned over to cover the body 20. The cover 20 is provided with a film keypad 21 coupled to the connector 111 and a second sensor 22 located to correspond to the first sensor 12. The second sensor 22 is coupled to the film keypad 21 to control the ON/OFF of the film keypad 21. The film keypad 21 is a newly-developed keypad, and it is constituted of a key layer, a circuit layer and a backlight layer. The film keypad 21 has a small thickness in a range from 0.1 mm to 0.5 mm. Thus, such a thin film keypad 21 provided on the protective sleeve 1 has no influence on the whole thickness of the protective sleeve 1. The coupling between the connector 111 and the film keypad 21 as well as the coupling between the second sensor 22 and the film keypad 21 can be achieved by electrical wires.

Optionally, as shown in FIG. 1, the bottom surface of the film keypad 21 is electrically connected to a circuit board 23. The circuit board 23 may be inserted into the cover 20. A touch pad 231 is provided on the circuit board 23, so that the user can utilize the touch pad 231 to move a cursor on the touch screen 110 when using the film keypad 21. Of course, the cover 20 may be only provided with the film keypad 21 without the circuit board 23 and the touch pad 231.

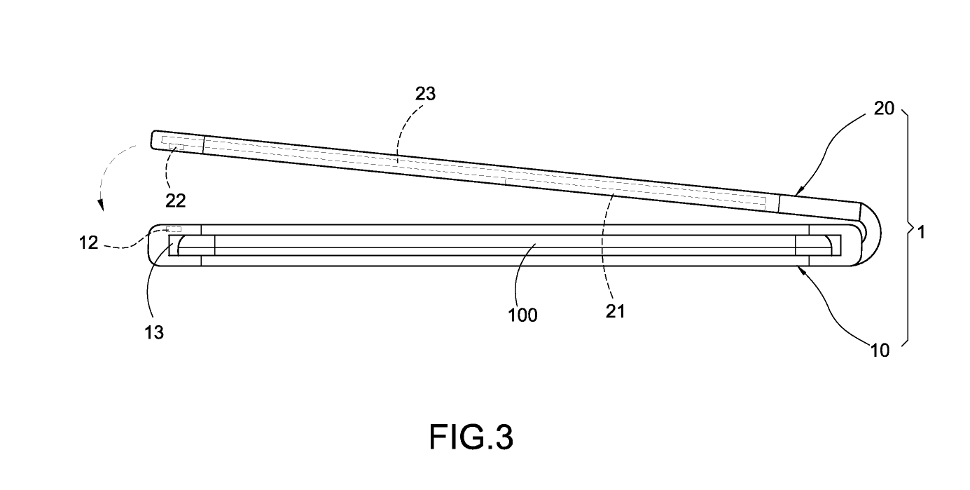

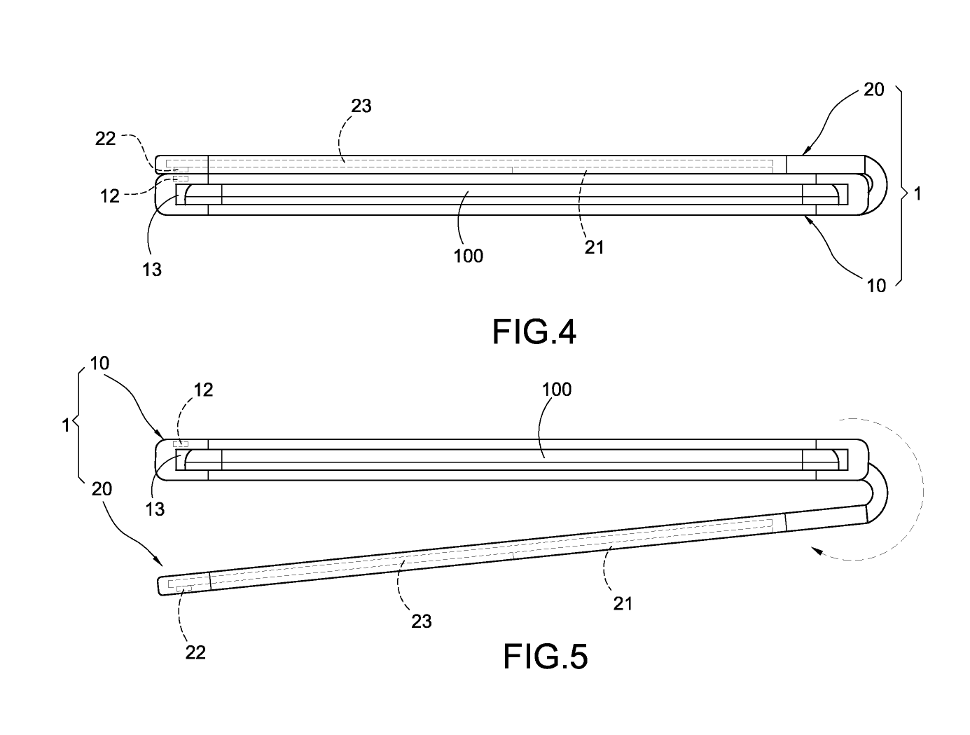

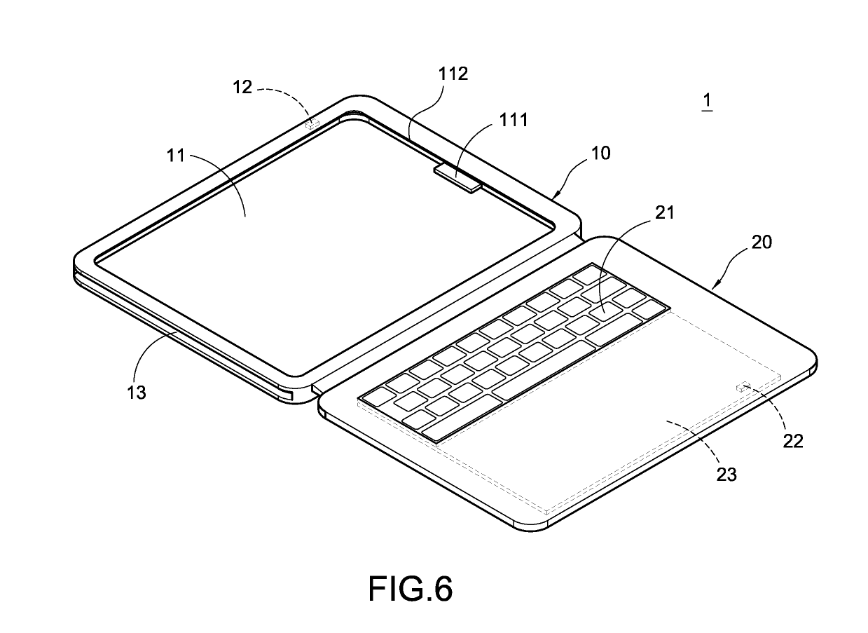

As shown in FIG. 1, the second sensor 22 is provided on the circuit board 23 to correspond to the first sensor 12 of the body 10. Of course, the location of the first sensor 12 on the body 10 and the location of the second sensor 22 on the cover 20 can be adjusted arbitrarily as long as the first sensor 12 and the second sensor 22 sense with each other to turn off the film keypad 21 (as shown in FIGS. 3 and 4) when the cover 20 is turned over to cover the upper surface of body 10. Further, if the user turns over the cover 20 in an opposite direction to cover the bottom surface of the body 10, as shown in FIG. 5, the first sensor 12 and the second sensor 22 can still sense with each other to turn off the film keypad 21 as long as the distance between the first sensor 12 and the second sensor 22 does not exceed their mutual sensing range.

It should be noted that, the film keypad 21 may be electrically connected to the connector 111 of the body 10 through a flexible flat cable (not shown), or wirelessly connected to the connector 111 by means of infrared or Bluetooth transmission. In this way, the characters or commands input by the film keypad 21 can be transmitted to the connector 111 of the body 10, then to the signal receiving unit 120 of the touch control electronic device 100, and finally to the touch screen 110 by means of the flexible flat cable or the wireless transmission. On the other hand, electricity is supplied to the film keypad 21 through the flexible flat cable or wireless transmission. When the cover 20 covers the upper surface of the body 10 as shown in FIG. 4 or the cover 20 is turned over to cove the bottom surface of the body 10 as shown in FIG. 5 with the first sensor 12 and the second sensor 22 sensing with each other, the coupling between the film keypad 21 and the connector 111 will be shut off temporarily to thereby turn off the film keypad 21. At this time, the user cannot input characters or commands through the film keypad 21. Thus, even though the user covers the cover 20 on the upper surface or the bottom surface of the body 10 without turning off the power of the touch control electronic device 100, the first sensor 12 and the second sensor 22 can still sense with each other to turn off the film keypad 21. Therefore, the problem that the keys of the film keypad 21 may be unintentionally activated to input commands can be avoided.

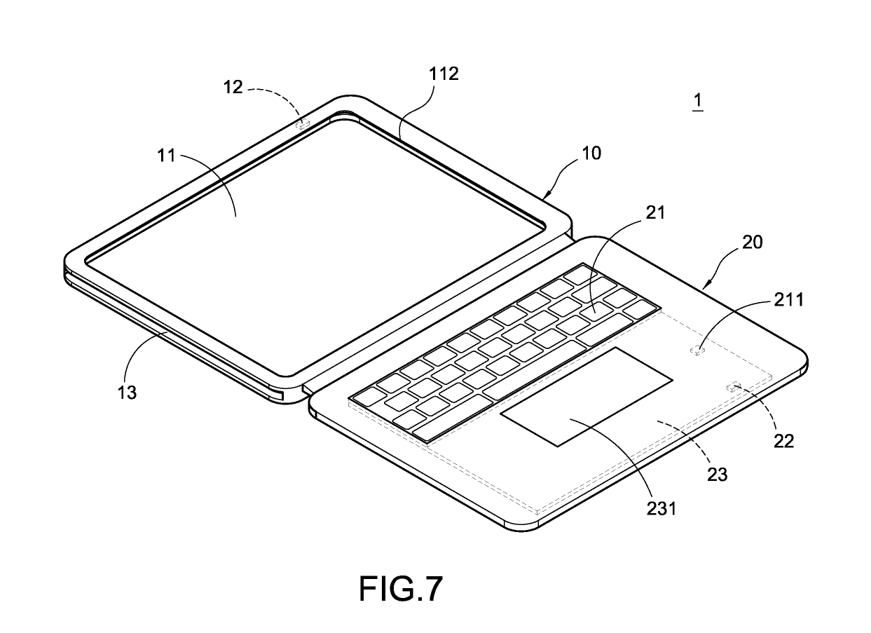

Please refer to FIG. 7, which shows another embodiment of the present invention. The difference between the present embodiment and the previous embodiment lies in that: a wireless transceiver 211 is provided in the film keypad 21 to be coupled with the signal receiving unit 120 of the touch control electronic device 100 by means of wireless Bluetooth transmission. In other word, the signal receiving unit 120 is a wireless receiving unit, so that the connector 111 of the body 10 may be omitted. Such a modification can be easily thought by those skilled in this art in view of the above teachings of the present invention and existing technology.

In the above embodiments of the present invention, although the touch control electronic device 100 is exemplified as a portable panel computer, those skilled in this art may easily understand that the size of the protective sleeve 1 of the present invention is not limited to the size of the portable panel computer only but may be applied to a smart phone, personal digital assistant or other small touch control electronic device 100.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A protective sleeve for a touch control electronic device, the touch control electronic device having a touch screen and a signal receiving unit, the protective sleeve including:
a body having an accommodating portion for receiving the touch control electronic device, the accommodating portion being provided with an opening for showing the touch screen, the body being provided with a first sensor; and
a cover connected to one side of the body and turned over to cover the body, the cover being provided with a film keyboard coupled to the signal receiving unit and a second sensor located to correspond to the first sensor, the second sensor being coupled to the film keypad to control the ON/OFF of the film keypad;
wherein the first sensor and the second sensor sense with each other to turn off the film keypad when the cover covers the body.

2. The protective sleeve for a touch control electronic device according to claim 1, wherein the signal receiving unit is a wired receiving unit.

3. The protective sleeve for a touch control electronic device according to claim 2, wherein the accommodating portion has a connector electrically connected to the signal receiving unit, the film keypad is coupled to the connector.

4. The protective sleeve for a touch control electronic device according to claim 3, wherein the coupling between the connector and the film keypad as well as the coupling between the film keypad and the second sensor are achieved by electrical wires.

5. The protective sleeve for a touch control electronic device according to claim 3, wherein the coupling between the connector and the film keypad as well as the coupling between the film keypad and the second sensor are achieved by wireless transmission.

6. The protective sleeve for a touch control electronic device according to claim 3, wherein the coupling between the connector and the film keypad is achieved by electrical wires, whereas the coupling between the film keypad and the second sensor is achieved by wireless transmission.

7. The protective sleeve for a touch control electronic device according to claim 3, wherein the coupling between the connector and the film keypad is achieved by wireless transmission, whereas the coupling between the film keypad and the second sensor is achieved by electrical wires.

8. The protective sleeve for a touch control electronic device according to claim 1, wherein the signal receiving unit is a wireless receiving unit.

9. The protective sleeve for a touch control electronic device according to claim 8, wherein the film keypad is provided with a wireless transceiver coupled to the signal receiving unit by wireless Bluetooth transmission.

10. The protective sleeve for a touch control electronic device according to claim 9, wherein the coupling between the film keypad and the second sensor is achieved by electrical wires.

11. The protective sleeve for a touch control electronic device according to claim 9, wherein the coupling between the film keypad and the second sensor is achieved by wireless transmission.

12. The protective sleeve for a touch control electronic device according to claim 1, wherein the protective sleeve is made of flexible materials including rubber by integrally forming the body and cover together.

13. The protective sleeve for a touch control electronic device according to claim 1, wherein the first sensor is provided on a periphery of the opening of the body.

14. The protective sleeve for a touch control electronic device according to claim 1, wherein one side of the body is provided with a through slot in communication with the accommodating portion, the touch control electronic device is inserted into the accommodating portion via the through slot.

15. The protective sleeve for a touch control electronic device according to claim 1, wherein the body is made of flexible materials, the touch control electronic device is disposed into the accommodating portion by enlarging the flexible opening.

16. The protective sleeve for a touch control electronic device according to claim 1, wherein a bottom surface of the film keypad is electrically connected to a circuit board, the circuit board is inserted into the cover.

17. The protective sleeve for a touch control electronic device according to claim 16, wherein the circuit board is provided with a touch pad.

18. The protective sleeve for a touch control electronic device according to claim 16, wherein the second sensor is provided on the circuit board to correspond to the first sensor of the body.
